(19) United States
(12) Patent Application Publication
(10) Pub. No.: US 2011/0143545 A1
(43) Pub. Date: Jun. 16, 2011

(54) APPARATUS AND METHOD OF TREATING SURFACE OF SEMICONDUCTOR SUBSTRATE

(76) Inventors: Hisashi OKUCHI, Yokohama-Shi (JP); Tatsuhiko Koide, Yokkaichi-Shi (JP); Shinsuke Kimura, Yokkaichi-Shi (JP); Yoshihiro Ogawa, Yokkaichi-Shi (JP); Hiroshi Tomita, Yokohama-Shi (JP)

(21) Appl. No.: 12/879,097

(22) Filed: Sep. 10, 2010

(30) Foreign Application Priority Data
Dec. 15, 2009 (JP) 2009-284361

(51) Int. Cl. H01L 21/306; B08B 3/00

(52) U.S. Cl. 438/706; 134/95.1; 257/E21.224; 257/E21.215

(57) ABSTRACT

In one embodiment, an apparatus of treating a surface of a semiconductor substrate comprises a substrate holding and rotating unit which holds a semiconductor substrate with a surface having a convex pattern formed thereon and rotates the semiconductor substrate, a first supply unit which supplies a chemical and/or pure water to the surface of the semiconductor substrate, and a second supply unit which supplies a diluted water repellent to the surface of the semiconductor substrate to form a water-repellent protective film on the surface of the convex pattern. The second supply unit comprises a buffer tank which stores the water repellent, a first supply line which supplies a purge gas to the buffer tank, a second supply line which supplies a diluent, a pump which sends off the water repellent within the buffer tank, a third supply line which supplies the water repellent sent off from the pump, and a mixing valve which mixes the diluent and the water repellent to produce the diluted water repellent.

### CROSS REFERENCE TO RELATED APPLICATION

This application is based upon and claims benefit of priority from the Japanese Patent Application No. 2009-284361, filed on Dec. 15, 2009, the entire contents of which are incorporated herein by reference.

### FIELD

Embodiments described herein relate generally to an apparatus and a method of treating surface of a semiconductor substrate.

### BACKGROUND

The process of manufacturing a semiconductor device includes various processes, such as a lithography process, an etching process and an ion implantation process. After completion of each process, a cleaning process and a drying process for removing impurities and residues remaining on a wafer surface to clean the wafer surface are performed before the transfer to the next process.

In recent years, as progress has been made in miniaturization of elements, a problem has arisen in that, during development and drying of resist patterns after the lithography process (exposure and development), the resist patterns are collapsed due to capillarity. To solve such a problem, a method of making the surfaces of resist patterns water-repellent to decrease capillary forces acting between the resist patterns and developer as well as between the resist patterns and pure water for rinsing has been proposed (see, e.g., Japanese Patent Application Laid-Open No. 7-142349). Under this method, an organic matter is adhered onto the surfaces of resist patterns; however, the organic matter is removed together with the resist patterns in the etching process after the lithography process.

For example, in cleaning treatment of a wafer after the etching process, a chemical for the cleaning treatment is supplied onto the surface of the wafer, and then pure water is supplied to perform rinsing. After the rinsing, drying is performed which removes the pure water remaining on the wafer surface and dries the wafer.

As the method of performing the drying, there is known a method which uses isopropyl alcohol (IPA) and substitutes IPA for pure water on a wafer to dry the wafer (see, e.g., Japanese Patent No. 3866130). However, there has been a problem in that, during the drying, the actual device patterns formed on the wafer are collapsed by the surface tension of a liquid. Even with hydrofluoroether (HFE) having lower surface tension than IPA, it has been difficult to restrain the pattern collapse.

To solve such problems, supercritical drying in which the surface tension becomes zero has been proposed. However, the degree of perfection of the supercritical drying is low in terms of the processing equipment for a large-diameter wafer. Due to various kinds of legal regulations are applied over the use of high pressure gas, it is difficult to apply the supercritical drying to mass production processes. Further, the supercritical drying has had a problem in that, when moisture or the like is carried into a chamber which provides a supercritical atmosphere, collapse of patterns cannot be prevented.

### BRIEF DESCRIPTION OF THE DRAWINGS

FIG. 1 is a schematic configuration diagram of an apparatus of treating the surface of a semiconductor substrate according to an embodiment of the present invention;

FIG. 2 is a flowchart showing a method of treating the surface of a semiconductor substrate according to the embodiment;

FIG. 3A is a graph showing a relationship between a cleaning sequence and the contact angle of water with the pattern;

FIG. 3B is a graph showing a relationship between a cleaning sequence and the contact angle of water with the pattern;

FIG. 4 is a diagram showing the surface tension of a liquid which acts on patterns;

FIG. 5A is a diagram showing a state of patterns after drying in which water-repellent protective films are not formed;

FIG. 5B is a diagram showing a state of patterns after the drying in which water-repellent protective films are formed;

FIG. 6 is a graph showing an exemplary relationship between: the distance from a position at which a water repellent and a diluent are mixed to a position at which the diluted water repellent is discharged; and the contact angle of water with the pattern after water-repellent treatment; and

FIG. 7 is a schematic configuration diagram of an apparatus of treating the surface of a semiconductor substrate according to a modification.

### DETAILED DESCRIPTION

In one embodiment, an apparatus of treating a surface of a semiconductor substrate comprises a substrate holding and rotating unit which holds a semiconductor substrate with a surface having a convex pattern formed thereon and rotates the semiconductor substrate, a first supply unit which supplies a chemical and/or pure water to the surface of the semiconductor substrate held in the substrate holding and rotating unit, and a second supply unit which supplies a diluted water repellent to the surface of the semiconductor substrate held in the substrate holding and rotating unit to form a water-repellent protective film on the surface of the convex pattern. The second supply unit comprises a buffer tank which stores the water repellent, a first supply line which supplies a purge gas to the buffer tank, a second supply line which supplies a diluent, a pump which sends off the water repellent within the buffer tank, a third supply line which supplies the water repellent sent off from the pump, a mixing valve which is connected to the second supply line and the third supply line and which mixes the diluent and the water repellent to produce the diluted water repellent, and a nozzle which discharges the diluted water repellent produced in the mixing valve to the surface of the semiconductor substrate.

An object to be performed in the washing process in the manufacturing process of a semiconductor device is to return a semiconductor substrate surface to a clean surface state without generating any defect (missing pattern, scratch, thinned pattern, dug substrate, or the like) in a fine pattern structure formed on a semiconductor substrate. Specifically, target matters to be washed includes resist material used in a lithography process, a reaction by-product (residue) remaining on a semiconductor wafer surface in a dry etching process, and metallic impurity, organic contaminant or the like, these processes are generally employed in a semiconductor manufacturing process. If the wafer is flown to the following manufacturing process while leaving the target materials to be washed, a device manufacturing yield ratio has to be lowered.

Accordingly, the cleaning process has an important role of forming a clean semiconductor wafer surface after cleaning without generating any defect (missing pattern, scratch, thinned pattern, dug substrate, or the like) in a fine pattern structure formed on the semiconductor substrate. As an element is miniaturized, cleanliness demanded in the cleaning process becomes higher.

On the other hand, in a recent structure in which a convex fine pattern of high aspect is provided (for example, a structure having pattern size of 30 nm or less, and an aspect ratio of 10 or more), since hydrophobic force is insufficient only by applying hydrophobic technique which is used in the resist process, it has been difficult to suppress collapse of the pattern. Further, there has been a problem with this method that the pattern surface is contaminated. In accordance with the following embodiment, it is possible to achieve higher hydrophobic contact than the conventional one and to suppress the pattern collapse, while keeping the pattern surface clean, with respect to the structure having the convex fine pattern of high aspect.

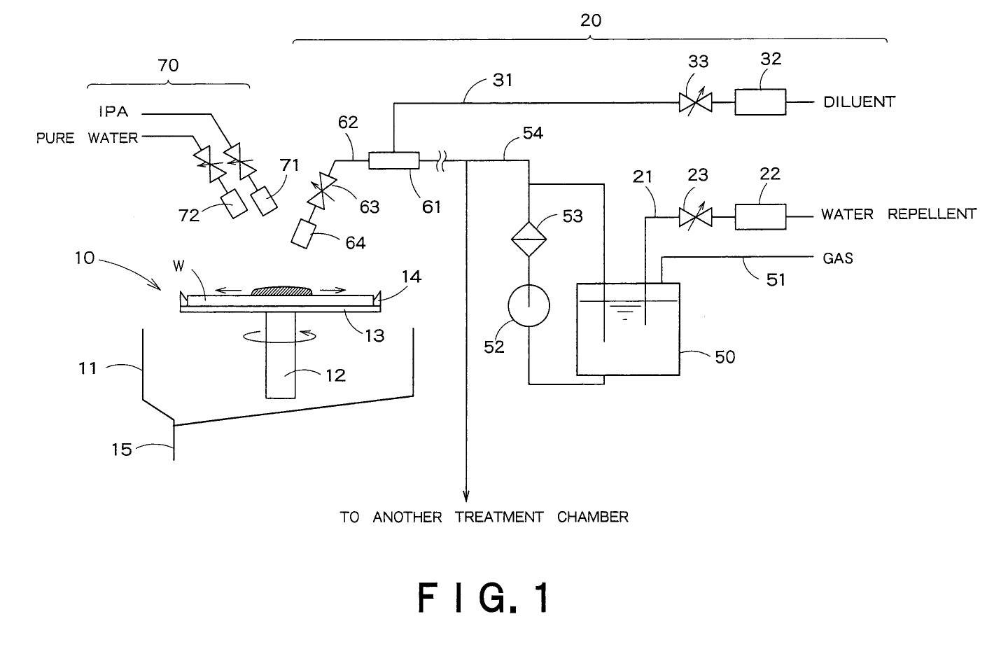

FIG. 1 shows a schematic configuration of an apparatus of treating the surface of a semiconductor substrate (hereinafter referred to as a “surface treatment apparatus”) according to an embodiment of the invention. The surface treatment apparatus comprises a substrate holding and rotating unit 10, a diluted water repellent supply unit 20 and a chemical supply unit 70.

The substrate holding and rotating unit 10 has a spin cup 11 included in a treatment chamber, a shaft 12, a spin base 13 and chuck pins 14. The shaft 12 extends in an approximately vertical direction, and the disk-shaped spin base 13 is mounted on the top edge of the shaft 12. The shaft 12 and the spin base 13 can be rotated by a motor (not shown).

The chuck pins 14 are provided at circumferential portions of the spin base 13. The chuck pins 14 grasp a substrate (wafer) W, which enables the substrate holding and rotating unit 10 to rotate the substrate W while keeping it nearly horizontal.

When a liquid has been supplied to the vicinity of the rotation center of the surface of the substrate W from the diluted water repellent supply unit 20 or the chemical supply unit 70, the liquid spreads in the radial direction of the substrate W. Extra liquid which has scattered in the radial direction of the substrate W is captured by the spin cup 11 and is expelled through a waste liquid tube 15.

The diluted water repellent supply unit 20 supplies a diluted water repellent to the substrate W held in the substrate holding and rotating unit 10. The water repellent is a chemical which makes the surfaces of convex patterns formed on the surface of the substrate W be water repellent. The water repelling of the surfaces of convex patterns will be described later.

The water repellent is stored in a buffer tank 50 through a chemical supply line (piping) 21. The water repellent is, for example, a silane coupling agent. The silane coupling agent has, in its molecule, a hydrolyzable group having reactivity with a hydroxyl group and an organic functional group having an affinity for an organic material. For example, hexamethyldisilazane (HMDS), tetramethylsilyldiethylamine (TMSDEA) and the like can be used as the silane coupling agent.

The chemical supply line 21 is provided with a flowmeter 22 and a valve 23. This allows the amount of supply to the buffer tank 50 to be controlled.

Upon being brought into contact with the atmosphere containing moisture, the water repellent deteriorates to decrease the water-repellent performance on the surfaces of convex patterns. To prevent such deterioration, an inert gas, such as an N₂ gas, or a gas having a low humidity is supplied as a purge gas through a gas supply line 51 to the buffer tank 50.

The water repellent within the buffer tank 50 is expelled by a pump 52, passes through a filter 53, and is supplied through a chemical supply line 54 to a mixing valve 61. A part of the water repellent which has passed through the filter 53 is returned to the buffer tank 50 to establish a circulation.

The diluent is supplied through a chemical supply line 31 to the mixing valve 61. The chemical supply line 31 is provided with a flowmeter 32 and a valve 33. This allows the amount of supply to the mixing valve 61 to be controlled. Low-priced chemicals including alcoholic materials, such as ethanol and IPA, and thinner-based materials, such as cyclohexanone and propylene glycol monomethyl ether (PGME), are used as the diluent.

The mixing valve 61 is connected to the chemical supply line 54 and the chemical supply line 31, and mixes the water repellent and the diluent. The diluted water repellent which has been expelled from the mixing valve 61 passes through a chemical supply line 62 and is discharged from a nozzle 64 to be supplied to the surface of the substrate W. The chemical supply line 62 is provided with a valve 63. This allows control of the amount of supply and the flow rate of the diluted water repellent to the surface of the substrate W.

The water repellent reacts to a hydroxyl group contained in the diluent and a hydroxyl group generated as reactive intermediates to decrease the water-repellent performance on the surfaces of convex patterns. As the time period from the mixing of the water repellent and the diluent to the supplying of the diluted water repellent to the surface of the substrate W is longer, the water-repellent performance becomes lower. Accordingly, the position at which the water repellent and the diluent are mixed (the position of the mixing valve 61) preferably be as close to the nozzle 64 as possible. The openings and other settings of the mixing valve 61 and the valve 63 are made so that the time period from the mixing of the water repellent and the diluent to the discharging of the diluted water repellent from the nozzle 64 is within a given time.

The chemical supply line 54 branches at an upstream side of the mixing valve 61, so as to supply the water repellent to another treatment chamber. In another treatment chamber, similarly, the water repellent and the diluent are mixed immediately before they are discharged from the nozzle, and the diluted water repellent is supplied to the substrate surface.

A small amount of water repellent is needed for water-repellent treatment of the surfaces of convex patterns formed on the wafer W. However, in order to perform highly efficient water-repellent treatment of a large-diameter wafer having a diameter of about 300 mm, the required amount of liquid is to such an extent that the entire wafer is immersed. The diluting of a water repellent with a low-priced diluent makes it possible to perform water-repellent treatment at low cost while supplying a required amount of water repellent to the wafer surface.

The chemical supply unit 70 includes a nozzle 71 and a nozzle 72 which supply IPA and pure water, respectively, to the surface of the substrate W. The chemical supply unit 70 includes another nozzle (not shown) which supplies another chemical, such as a sulfuric acid/hydrogen peroxide mixture (SPM), or a mixed liquid of sulfuric acid and a hydrogen peroxide solution, to the surface of the substrate W.

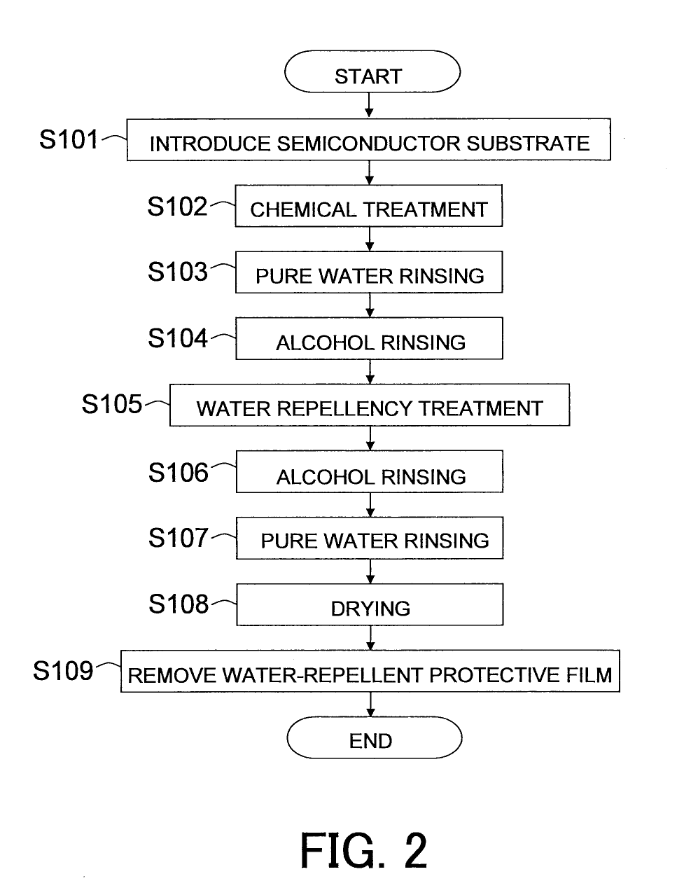

With reference to the flowchart shown in FIG. 2, a description is given of a method of treating the surface of a semiconductor substrate using such a surface treatment apparatus.

(Step S101) The semiconductor substrate W to be treated which has a plurality of convex patterns in a given area of the surface is carried in by a carrier (not shown), and is held in the substrate holding and rotating unit 10. The convex patterns are, for example, a line and space pattern. At least a part of the convex patterns may be formed of a film containing silicon. The convex patterns are formed by, for example, a reactive ion etching (RIE) method.

(Step S102) The semiconductor substrate W is rotated at a given rotational speed, and a chemical is supplied from the chemical supply unit 70 to the vicinity of the rotation center of the surface of the semiconductor substrate W. The chemical is, for example, SPM or standard clean 1 (SC-1).

Upon receiving centrifugal force caused by the rotation of the semiconductor substrate W, the chemical extends over the entire surface of the semiconductor substrate W to perform chemical (cleaning) treatment of the semiconductor substrate W.

(Step S103) Pure water is supplied from the chemical supply unit 70 to the vicinity of the rotation center of the surface of the semiconductor substrate W. Upon receiving centrifugal force caused by the rotation of the semiconductor substrate W, the pure water extends over the entire surface of the semiconductor substrate W. Thereby, pure water rinsing is performed which washes away the remaining chemical on the surface of the semiconductor substrate W.

(Step S104) Alcohol, such as IPA, is supplied from the chemical supply unit 70 to the vicinity of the rotation center of the surface of the semiconductor substrate W. Upon receiving centrifugal force caused by the rotation of the semiconductor substrate W, the IPA extends over the entire surface of the semiconductor substrate W. Thereby, alcohol rinsing is performed which substitutes IPA for the pure water remaining on the surface of the semiconductor substrate W.

(Step S105) A diluted water repellent is supplied from the diluted water repellent supply unit 20 to the vicinity of the rotation center of the surface of the semiconductor substrate W. The water repellent is, for example, a silane coupling agent.

Upon receiving centrifugal force caused by the rotation of the semiconductor substrate W, the diluted silane coupling agent extends over the entire surface of the semiconductor substrate W. Thereby, a protective film of low wettability with water (water-repellent protective film) is formed over the surfaces of the convex patterns.

The water-repellent protective film is formed as a result of an ester reaction of the silane coupling agent. Accordingly, the reaction may be promoted by annealing to raise the liquid temperature, and by irradiation with ultraviolet rays.

The water repellent and the diluent are mixed in the mixing valve 61 positioned near the nozzle 64. The diluted water repellent can be supplied to the surface of the semiconductor substrate W in a short time after the mixing. This makes it possible to reduce deterioration in water-repellent performance of the water repellent on the surfaces of the convex patterns.

In cases where convex patterns are silicon-based films of silicon nitride, poly silicon and the like, if silylation treatment using a silane coupling agent is performed, the silylation reaction could be insufficient, and thereby sufficient water repellency to restrain the collapse of the pattern can not be obtained. In this case, it is preferable that treatment with a treatment chemical containing an oxidizing agent capable of oxidizing the surface of a silicon-based material be added to change the surface of the silicon-based material to a silicon oxide-based chemical oxide film. Performing the silylation treatment after the added treatment enables the water repellency after the silylation treatment to be improved.

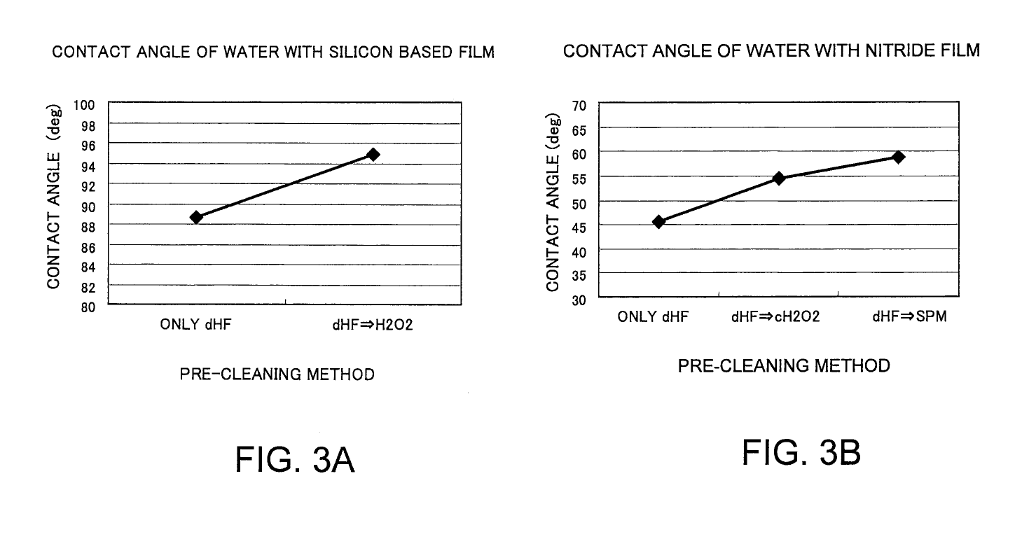

For example, in the case of a silicon-based film, as shown in FIG. 3A, when only dHF treatment is performed so as to form a water-repellent protective film, the contact angle of water with the pattern is 89 degree. Adding H₂O₂ treatment to the previous treatment improves the contact angle to 95 degree. This is considered because a moderate oxide film has been formed on the surface of the silicon-based film.

In the case of a silicon nitride film, as shown in FIG. 3B, when only dHF treatment is performed to form a water-repellent protective film, the contact angle of water is 46 degree. Adding H₂O₂ treatment to the previous treatment improves the contact angle to 54 degree, and adding SPM treatment improves the contact angle to 59 degree. This is considered because optimum modifying treatment is performed so that water-repellent treatment is readily applied to the substrate surface after cleaning, that is, the SiN surface is changed to SiO₂ by an oxidizing agent, so that a water-repellent protective film is likely to be formed.

After RIE processing, many processing residues are produced. In a state in which processing residues remain, a water-repellent protective film is less likely to be formed. Removing residues by SPM treatment and the like is effective in order to form a water-repellent protective film. Further, plasma damage caused by the RIE processing is accumulated to produce a dangling bond on the surface. To overcome this defect, when the surface is subjected to modifying treatment using a chemical with an oxidation effect, the dangling bond is modified with OH groups. If there exist a large number of OH groups, the probability for the silylation reaction becomes high. As a result, a water-repellent protective film is likely to be formed, and therefore higher water repellency can be obtained. In this example, the effect can be obtained even when fine patters are made of a silicon oxide film.

Note that, in the foregoing description, an example has been described in which, after cleaning of the semiconductor substrate W, the surface of the semiconductor substrate W is modified with a treatment chemical different from the cleaning chemical. If the cleaning chemical also has a modification effect, that is, it has an oxidation effect, modifying treatment may not be separately performed. However, separating the cleaning process from the modification process is preferable because, since the target surface of convex fine patterns is cleaned and then the cleaned surface is modified in this case, the modification effect can be more improved than the case of using a chemical having an oxidation effect.

(Step S106) Alcohol, such as IPA, is supplied from the chemical supply unit 70 to the vicinity of the rotation center of the surface of the semiconductor substrate W. Upon receiving centrifugal force caused by the rotation of the semiconductor substrate W, the IPA extends over the entire surface of the semiconductor substrate W. Thereby, alcohol rinsing is performed which substitutes IPA for an unreacted silane coupling agent remaining on the surface of the semiconductor substrate W.

(Step S107) Pure water is supplied from the chemical supply unit 70 to the vicinity of the rotation center of the surface of the semiconductor substrate W. Upon receiving centrifugal force caused by the rotation of the semiconductor substrate W, the pure water extends over the entire surface of the semiconductor substrate W. Thereby, pure water rinsing is performed in which the remaining IPA on the surface of the semiconductor substrate W is washed away with the pure water.

(Step S108) Drying of the semiconductor substrate W is performed. For example, spin drying is performed in which the rotational speed of the semiconductor substrate W is increased to a given spin dry rotational speed, so that the remaining pure water on the surface of the semiconductor substrate W is removed, and the substrate is dried.

The convex patterns formed on the semiconductor substrate W are covered with a water-repellent protective film, and therefore a contact angle θ of the liquid becomes large (close to 90°).

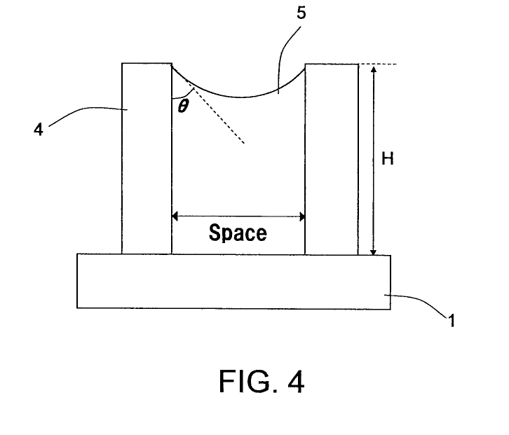

FIG. 4 shows a state in which a part of patterns 4 formed on the semiconductor substrate W is wet with a liquid 5. The force exerted on the pattern 4 is expressed by the following equation:

P=2×γ×cos θ·H/Space (1)

where the distance between the patterns 4 is Space, the height of the pattern 4 is H, and the surface tension of the liquid 5 is γ.

As the angle θ approaches 90°, cos θ approaches zero. It is shown that the surface tension P of the liquid acting on the pattern during drying decreases. This enables prevention of the patterns being collapsed at the time of the drying.

(Step S109) Ashing, such as dry ashing or ozone gas treatment, is performed to remove the water-repellent protective film formed on the convex pattern surfaces. Since this embodiment is to clean and dry the surface of a semiconductor substrate, the cleaning process is completed when the water-repellent protective film has been removed. Note that, in the case of removing the water-repellent protective film in a process after this process, the water-repellent protective film may not be removed immediately after drying.

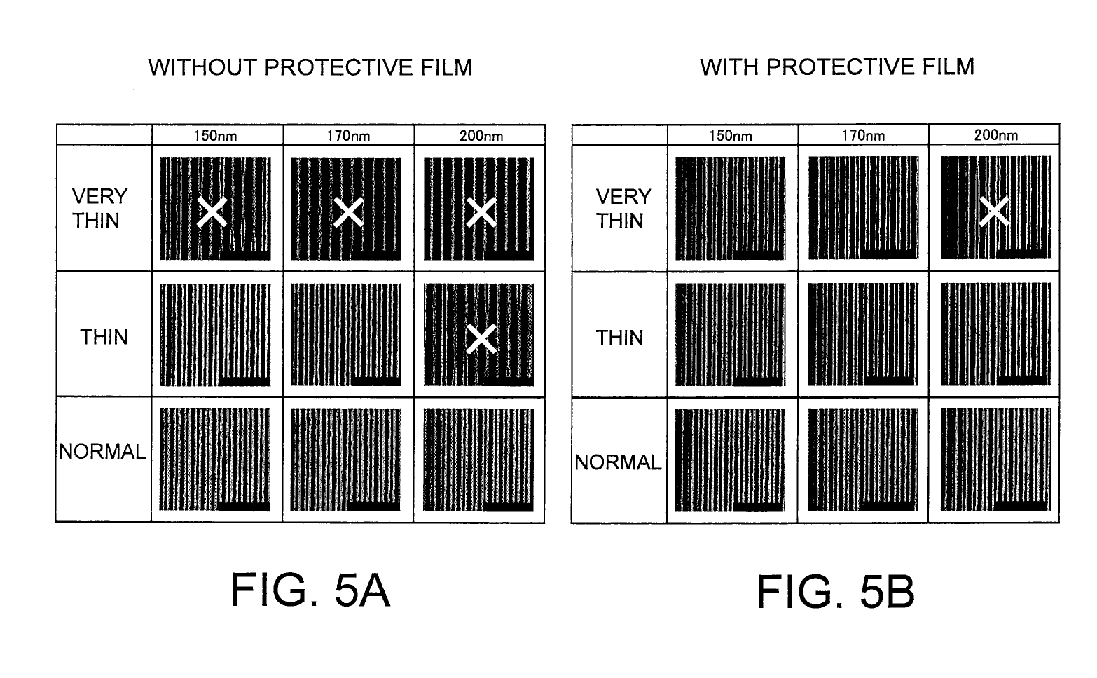

The states of patterns after the drying in cases where such a water-repellent protective film has not been formed and in cases where the protective film has been formed are shown in FIGS. 5A and 5B, respectively. For patterns having three kinds of line lengths, 150 nm, 170 nm and 200 nm, and three kinds of line widths, normal, thin and very thin (normal>thin>very thin), surface treatment has been performed.

As shown in FIG. 5A, in cases where the protective film is not formed, all patterns whose lines are very thin are collapsed although they have different line heights, 150 nm, 170 nm and 200 nm. A pattern whose line is thin and which has a line height of 200 nm is also collapsed.

On the other hand, as shown in FIG. 5B, when the water-repellent protective film is formed, all the patterns except a pattern whose line is very thin and which has a line height of 200 nm can be prevented from being collapsed. It is shown that the formation of the water-repellent protective film enables even a pattern having a high aspect ratio to be prevented from being collapsed by cleaning and drying, which leads to improvement in the collapse margin.

Thus, the surface treatment of the semiconductor substrate according to this embodiment enables a protective film having water repellency to be formed on the substrate surface at the time of cleaning the surface of the semiconductor substrate W, to prevent fine convex patterns from being collapsed during drying. A water repellent diluted with a low-priced diluent is used for formation of the water-repellent protective film, and therefore the cost can be reduced.

To prevent a pattern formed on the substrate from being collapsed, the force exerted on the pattern (P expressed by the foregoing equation 1) needs to be reduced. Among parameters of the equation 1, Space is a fixed parameter which is determined by the pattern dimension, the wettability cos θ is a fixed parameter which is determined by the relationship between a substance contained in (the surface of) a fine pattern and a liquid. Therefore, conventional substrate treatment has paid attention to the surface tension γ, and has struggled to reduce the force exerted on the pattern by using a liquid with smaller γ. However, decreasing of γ is limited to some extent, and therefore the pattern collapse has not been prevented.

In contrast, as described above, in a surface treatment method according to an embodiment of the present invention, a water-repellent protective film is formed on the pattern surface to control the wettability cos θ, thereby making very small the force exerted on the pattern during drying. This arrangement enables prevention of collapsed patterns.

A surface treatment method according to the foregoing embodiment is particularly effective for prevention of the pattern collapse when the aspect ratio is 8 or more.

In the foregoing embodiment, the alcohol rinsing is performed (steps S104 and S106) before and after the process of forming a water-repellent protective film (step S105). This is because the silane coupling agent used during the forming of the water-repellent protective film is sometimes, depending on its kind, not replaceable with pure water. Accordingly, in cases where the silane coupling agent being used is a substance replaceable with pure water, the alcohol rinsing can be omitted.

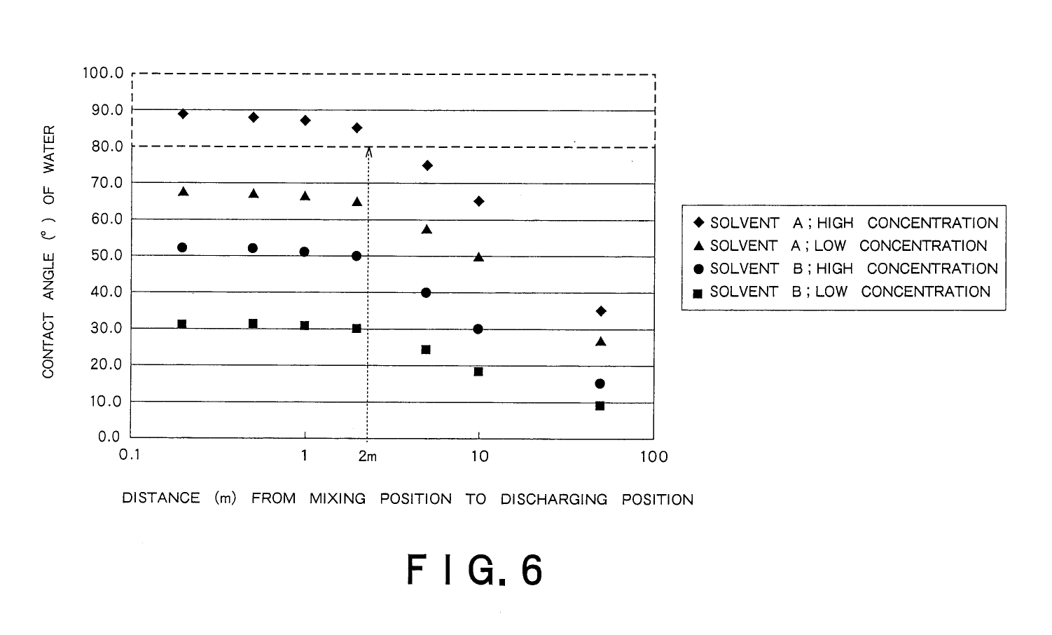

FIG. 6 shows one example of the relationships between: the distance from the position of mixing the water repellent and the diluent (position of the mixing valve 61) to the position of discharging the diluted water repellent (position of the nozzle 64); and the contact angle of water with the convex pattern after the water-repellent treatment.

The contact angle is preferably in the range from 80 to 100°, and, as shown in FIG. 6, the distance from the mixing position to the discharging position (the length of piping of the chemical supply line 62) is preferably within 2 m. The preferable distance from the mixing position to the discharging position is also dependent on the flow rate of a diluted water repellent in the chemical supply line 62. When the flow rate is high, the distance from the mixing position to the discharging position can be extended.

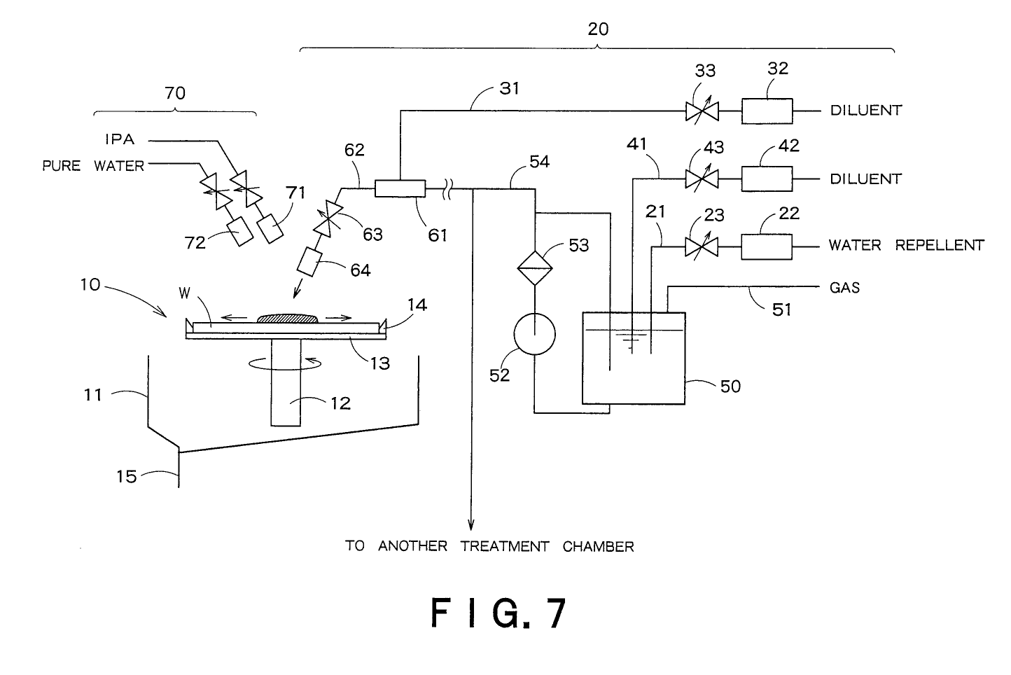

When a trace amount of water repellent (e.g., the diluted water repellent having a concentration of about 1%) is required for water-repellent treatment of the convex pattern surface on the semiconductor substrate W, a chemical supply line 41 may be provided as shown in FIG. 7, so that a diluent is supplied to the buffer tank 50 to perform a preliminary dilution and is stored in the buffer tank 50. The diluent for the preliminary dilution is a chemical which prevents a water repellent from deterioration. As the preliminary diluent, for example, toluene or propylene glycol methyl ether acetate (PGMEA) which is used in a thinner or the like, a solvent which has no hydroxyl group in compounds themselves, such as hexane and xylene, or a solvent which does not produce a hydroxyl group as an intermediate product is used. The water repellent which has been diluted in the buffer tank 50 is further diluted in the mixing valve 61. In the case of decreasing the water repellent concentration of a diluted water repellent in this way, the dilution process may be divided into two steps.

When the water repellent and the diluent are chemicals which deteriorate upon exposure to light, and piping and the like have a portion where these chemicals are exposed to light, it is preferable that a light shielding film or the like capable of shielding them from light be provided at the portion.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An apparatus of treating a surface of a semiconductor substrate, comprising:
a substrate holding and rotating unit which holds a semiconductor substrate with a surface having a convex pattern formed thereon and rotates the semiconductor substrate;
a first supply unit which supplies a chemical and/or pure water to the surface of the semiconductor substrate held in the substrate holding and rotating unit; and
a second supply unit which supplies a diluted water repellent to the surface of the semiconductor substrate held in the substrate holding and rotating unit to form a water-repellent protective film on the surface of the convex pattern,
the second supply unit comprising:
a buffer tank which stores the water repellent;
a first supply line which supplies a purge gas to the buffer tank;
a second supply line which supplies a diluent;
a pump which sends off the water repellent within the buffer tank;
a third supply line which supplies the water repellent sent off from the pump;
a mixing valve which is connected to the second supply line and the third supply line and which mixes the diluent and the water repellent to produce the diluted water repellent; and
a nozzle which discharges the diluted water repellent produced in the mixing valve to the surface of the semiconductor substrate.

2. The apparatus according to claim 1, wherein the second supply unit further comprises a fourth supply line which supplies a second diluent to the buffer tank.

3. The apparatus according to claim 2, wherein the second diluent is any one of toluene, PGMEA, hexane and xylene.

4. The apparatus according to claim 1, wherein a part of the water repellent sent off from the pump is returned to the buffer tank.

5. The apparatus according to claim 1, wherein the buffer tank stores a silane coupling agent as the water repellent.

6. The apparatus according to claim 1, wherein piping connecting the mixing valve with the nozzle has a length of 2 m or less.

7. The apparatus according to claim 1, wherein the first supply line supplies nitrogen gas as the purge gas.

8. The apparatus according to claim 1, wherein the diluent is any one of ethanol, isopropyl alcohol, acetone, cyclohexanone and PGME.

9. The apparatus according to claim 1, wherein at least a part of the second supply unit is provided with a light shielding film.

10. A method of treating a surface of a semiconductor substrate, comprising:
forming a plurality of convex patterns on the semiconductor substrate by dry etching;
cleaning and modifying surfaces of the convex patterns using a chemical;
forming a water-repellent protective film on the modified surfaces of the convex patterns using a diluted water repellent;
rinsing the semiconductor substrate using water after the forming of the water-repellent protective film;
drying the semiconductor substrate; and
removing the water-repellent protective film with the convex patterns left on the surface.

11. The method according to claim 10, wherein, within a given time after mixing a diluent and the water repellent, the diluted water repellent is supplied to the surfaces of the convex patterns to form the water-repellent protective film.

12. The method according to claim 10, wherein
the water repellent and a first diluent are mixed to create a first diluted water repellent,
a second diluent is mixed into the first diluted water repellent to create a second diluted water repellent, and
within a given time after mixing the first diluted water repellent and the second diluent, the second diluted water repellent is supplied to the surfaces of the convex patterns to form the water-repellent protective film.

13. The method according to claim 12, wherein the first diluent is any one of toluene, PGMEA, hexane and xylene, and the second diluent is any one of ethanol, isopropyl alcohol, acetone, cyclohexanone and PGME.

14. The method according to claim 10, wherein the water repellent is a silane coupling agent.

15. The method according to claim 14, wherein the semiconductor substrate is rinsed using alcohol at least one of a timing after modifying the surfaces of the convex patterns and before forming the water-repellent protective film and a timing after forming the water-repellent protective film and before rinsing using the water.
